(19) United States
(12) Patent Application Publication
(10) Pub. No.: US 2025/0232818 A1
(43) Pub. Date: Jul. 17, 2025

(54) STORAGE DEVICE BASED ON FLASH MEMORY AND READING OPERATION METHOD THEREOF

(71) Applicant: Samsung Electronics Co., Ltd., Suwon-si (KR)

(72) Inventors: Haejong JANG, Suwon-si (KR); Suhyun KIM, Suwon-si (KR); Hyunsook LEE, Suwon-si (KR); Seonghoon WOO, Suwon-si (KR)

(73) Assignee: Samsung Electronics Co., Ltd., Suwon-si (KR)

(21) Appl. No.: 18/794,202

(22) Filed: Aug. 5, 2024

(30) Foreign Application Priority Data
Jan. 16, 2024 (KR) 10-2024-0006736

(51) Int. Cl. G11C 16/26; G11C 16/04; G11C 16/08

(52) U.S. Cl. CPC G11C 16/26; G11C 16/0483; G11C 16/08

(57) ABSTRACT

A memory device including: a memory cell array including a plurality of memory cells; a page buffer circuit connected to the plurality of memory cells through bitlines and configured to read data stored in the plurality of memory cells in page units; and a column decoding circuit configured to output non-contiguous sub-pages among page data stored in the page buffer circuit as valid data based on sub-page bitmap information included in a read command during a read operation.

### CROSS-REFERENCE TO RELATED APPLICATIONS

This application claims priority under 35 U.S.C. § 119 to Korean Patent Application No. 10-2024-0006736 filed on Jan. 16, 2024, in the Korean Intellectual Property Office, the disclosures of which are incorporated by reference herein in their entireties.

### BACKGROUND

Example embodiments of the present inventive concepts described herein relate to a semiconductor memory device, and more particularly, relate to a storage device based on a flash memory and a read operation method thereof.

A semiconductor memory may be mainly classified as a volatile memory or a non-volatile memory. Read and write speeds of the volatile memory (for example, a DRAM or an SRAM) are fast, but the data stored in the volatile memory disappears (e.g., is lost) when power is turned off. In contrast, the non-volatile memory may retain data even when power is turned off. Therefore, the non-volatile memory may be used to store contents that must be preserved regardless of whether power is supplied or not.

A representative example embodiment of the non-volatile memory is a flash memory. The flash memory is widely used as a storage medium for audio and video data in information devices such as computers and a smartphones. Recently, high-capacity, high-speed input/output and low-power technologies for the flash memory are being actively researched for installation in mobile devices such as smartphones.

The non-volatile memory may perform a read operation on a page-by-page basis. The non-volatile memory may divide one page into a plurality of sub-pages during the read operation and output a valid sub-page among the plurality of sub-pages.

### SUMMARY

Example embodiments of the present inventive concepts provide a memory device performing a read operation by using a once transmitted read command which includes bitmap information indicating a location of a sub-page and offset information indicating a size of the sub-page and a storage device including the same.

According to some example embodiments, a memory device includes a memory cell array including a plurality of memory cells; a page buffer circuit connected to the plurality of memory cells through bitlines and configured to read data stored in the plurality of memory cells in page units; and a column decoding circuit configured to output non-contiguous sub-pages among page data stored in the page buffer circuit as valid data based on sub-page bitmap information included in a read command during a read operation.

According to some example embodiments, a memory device includes a memory cell array including a plurality of memory cells; an address decoder connected to the plurality of memory cells through wordlines and configured to select one wordline based on a read command; a page buffer circuit connected to the plurality of memory cells through bitlines and configured to temporarily store page data stored in memory cells connected to the selected wordline; and a column decoding circuit configured to output at least one sub-page selected among the page data based on sub-page offset information and sub-page bitmap information included in the read command as valid data.

According to some example embodiments, a storage device includes a memory device including a plurality of memory cells; and a memory controller configured to send a read command including sub-page bitmap information to the memory device to read data stored in the plurality of memory cells. The memory device configured to select a wordline based on the read command and output non-contiguous sub-pages as valid data based on the sub-page bitmap information among page data stored in memory cells connected to the selected wordline.

### BRIEF DESCRIPTION OF THE DRAWINGS

The above and other objects and features of the present inventive concepts will become apparent by describing in detail some example embodiments thereof with reference to the accompanying drawings.

FIG. 1 is a block diagram illustrating a user device according to some example embodiments.

FIG. 2 is a block diagram illustrating an example of the memory device illustrated in FIG. 1 according to some example embodiments.

FIG. 3 is a circuit diagram illustrating an example of a memory block BLK1 of the memory cell array illustrated in FIG. 2 according to some example embodiments.

FIG. 4 is a circuit diagram illustrating cell strings selected by the first string selection line SSL1 among the cell strings of the memory block BLK1 illustrated in FIG. 3 according to some example embodiments.

FIG. 5 is a block diagram illustrating the memory controller of FIG. 1 according to some example embodiments.

FIG. 6 is a diagram illustrating a first read mode of a memory device of FIG. 2 according to some example embodiments.

FIG. 7 is a diagram illustrating configuration of read commands according to a first read mode of FIG. 6 according to some example embodiments.

FIG. 8 is a diagram illustrating a second read mode of a memory device of FIG. 2 according to some example embodiments.

FIG. 9 is a diagram illustrating configuration of read commands according to a second read mode of FIG. 8 according to some example embodiments.

FIG. 10 is a diagram illustrating bitmap information corresponding to valid data including non-contiguous sub-pages in a second read mode of a memory device of FIG. 2 according to some example embodiments.

FIG. 11 is a diagram illustrating an example embodiment of a column decoding circuit of FIG. 2 according to some example embodiments.

FIG. 12 is a diagram illustrating an example of a reading method of a memory device of FIG. 2 according to some example embodiments.

FIG. 13 is a diagram illustrating an example of a column decoding circuit of FIG. 2 according to some example embodiments.

FIG. 14 is a diagram illustrating a lookup table according to an example of a reading method of a memory device of FIG. 2 according to some example embodiments.

### DETAILED DESCRIPTION

Below, some example embodiments of the present inventive concepts will be described in detail and clearly to such an extent that an ordinary person of skill in the art may easily implement the present inventive concepts.

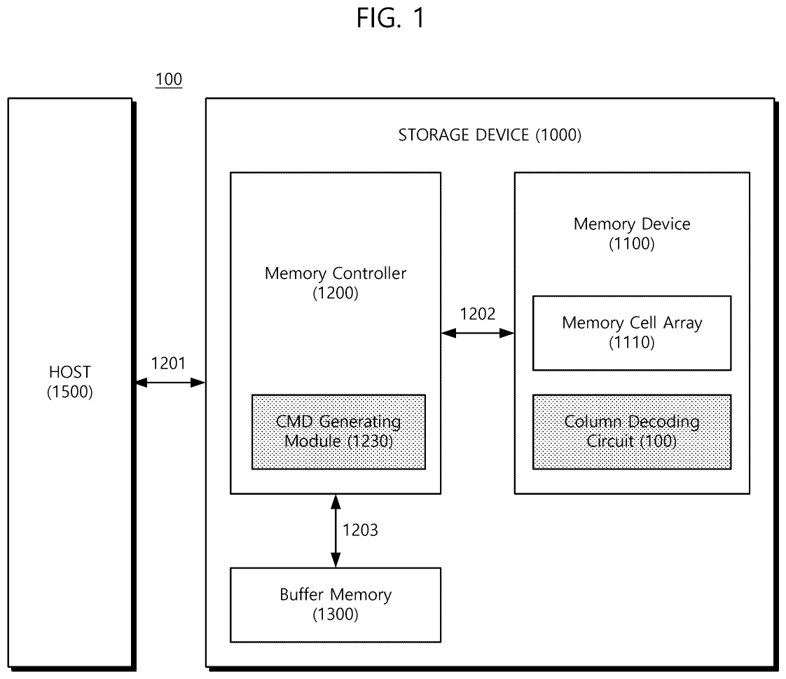

FIG. 1 is a block diagram illustrating a user device according to some example embodiments. Referring to FIG. 1, the user device 100 may include a storage device 1000 and a host 1500. The storage device 1000 and the host 1500 may be connected through a host interface 1201. The host interface 1201 may be a standard interface such as ATA, SATA, PATA, USB, SCSI, ESDI, IEEE 1394, IDE, and/or card interface, etc.

According to some example embodiments, the storage device 1000 may be a storage device based on a non-volatile memory. For example, the storage device 1000 may include a memory device 1100, a memory controller 1200, and a buffer memory 1300. The memory device 1100 may be a non-volatile memory such as a flash memory or phase change memory (PRAM). In some example embodiments, when the memory device 1100 is a flash memory, the storage device 1000 may be a flash storage device based on the flash memory. For example, the storage device 1000 may be an SSD (solid-state drive), UFS (universal flash storage), and/or memory card, etc. The buffer memory 1300 may include volatile memory (for example, DRAM).

According to some example embodiments, the memory device 1100 may be connected to the memory controller 1200 through a memory interface 1202. The memory device 1100 may include a memory cell array 1110 and a peripheral circuit. The peripheral circuit may include all analog or digital circuits required to store or read data in the memory cell array 1110.

According to some example embodiments, the peripheral circuit may receive external power from the memory controller 1200 and generate various levels of internal power. The peripheral circuit may receive commands, addresses, and data from the memory controller 1200, and store the data in the memory cell array 1110 according to the control signals. In some example embodiments, the peripheral circuit may read data stored in the memory cell array 1110 and provide the data to the memory controller 1200.

According to some example embodiments, the memory cell array 1110 may include a plurality of memory blocks. Each memory block may have a vertical three-dimensional structure. Each memory block may include a plurality of memory cells. Multi-bit data may be stored in each memory cell. For example, the memory device 1100 may be a TLC flash memory capable of storing 3 bits of data in one memory cell.

According to some example embodiments, the memory cell array 1110 may be located next to or above the peripheral circuit due to the design arrangement structure. The structure in which the memory cell array 1110 is located above the peripheral circuit is called a COP (cell on peripheral) structure. The memory cell array 1110 may be manufactured as a separate chip from the peripheral circuit. The upper chip including the memory cell array 1110 and the lower chip including the peripheral circuit may be connected to each other using a bonding method. This structure is called C2C (chip to chip) structure.

According to some example embodiments, the memory controller 1200 may be connected between the memory device 1100 and the host 1500. In some example embodiments, the memory controller 1200 may be connected between the buffer memory 1300 and the host 1500. The memory controller 1200 may control read or write operations of the memory device 1100 and/or the buffer memory 1300 in response to a request from the host 1500. The memory controller 1200 may receive host data from the host 1500 and provide, transmit, or send the host data to the memory device 1100 and/or the buffer memory 1300.

According to some example embodiments, the memory controller 1200 may include a control unit and a work memory (not illustrated). The control unit may control overall operations of the memory controller 1200. For example, the control unit may control a flash translation layer (FTL) to perform an address mapping operation. The control unit may be a commercially available or custom microprocessor.

According to some example embodiments, the work memory may be cache memory (for example, a SRAM). The work memory may serve as a buffer memory that may temporarily store data. In some example embodiments, the work memory may be a driving memory of the memory controller 1200. The work memory may drive the FTL.

According to some example embodiments, the FTL may be firmware or a program for efficiently managing the memory device 1100. The memory device 1100 may not support an overwrite function different from a hard disk drive. Therefore, the memory device 1100 may perform the following process while updating data written to a page. First, the memory device 1100 may copy all valid data in the first memory block to which the written page belongs to an empty second memory block. Second, the memory device 1100 may erase the first memory block and make it an empty memory block. The memory device 1100 may perform a large number of page copy operations (for example, a page read operation and/or a page write operation) and erase operations while going through this process.

According to some example embodiments, the FTL may be used between the host 1500 and the memory device 1100 to reduce the number of page copy and erase operations. The FTL may perform an address mapping function, a garbage collection function, and a wear-leveling function, etc. When an overwrite request is received from the host 1500, the address mapping function may write the corresponding data to another empty page instead of overwriting the original page, thereby reducing additional page copy and block erase operations. For this purpose, an address mapping table having a specified, certain, or alternatively desired, size must be maintained in the work memory and the buffer memory 1300. Through this, the FTL may manage an operation of mapping a logical address received from the host 1500 to a physical address in the memory device 1100.

According to some example embodiments, the buffer memory 1300 may be connected to the memory controller 1200 through a buffer interface 1203. For example, the buffer memory 1300 may be used to temporarily store data to be stored in or read from the memory device 1100. In some example embodiments, a cache area capable of storing cache data may be allocated to the buffer memory 1300. The buffer memory 1300 may be implemented with a DRAM (dynamic random-access memory) and a SRAM (static random-access memory), etc. The buffer memory 1300 may be included in the memory device 1100 or the memory controller 1200.

According to some example embodiments, the host 1500 may include a processor and a host memory (not illustrated). The processor and the host memory may be connected via an address/data bus. The host 1500 may be a personal digital assistant (PDA), a computer, a digital audio player, a digital camera, and/or a mobile phone, etc., but example embodiments are not limited thereto. The host memory may be a non-volatile or volatile memory in the form of a cache, a ROM (read-only memory), a PROM (programmable read-only memory), an EPROM (erasable programmable read-only memory), an EEPROM (electrically erasable programmable read-only memory), a flash, a SRAM, a DRAM, or the like.

According to some example embodiments, the host memory may drive a plurality of software or firmware. For example, the host memory may drive an operating system (OS), applications, a file system, a memory manager, and I/O drivers, etc.

According to some example embodiments, the memory controller 1200 may include a command generating module 1230. For example, the memory controller 1200 may receive various requests from the host 1500. The command generating module 1230 may generate a command for controlling a memory operation of the memory device 1100 based on a request received from the host 1500. As an example, the command generating module 1230 may set a format of the command CMD.

According to some example embodiments, the memory device 1100 may include a column decoding circuit 100. For example, the memory device 1100 may receive various commands from the memory controller 1200. During a read operation, the column decoding circuit 100 may decode a read command received from the memory controller 1200 to determine valid data read from the memory cell array 1110.

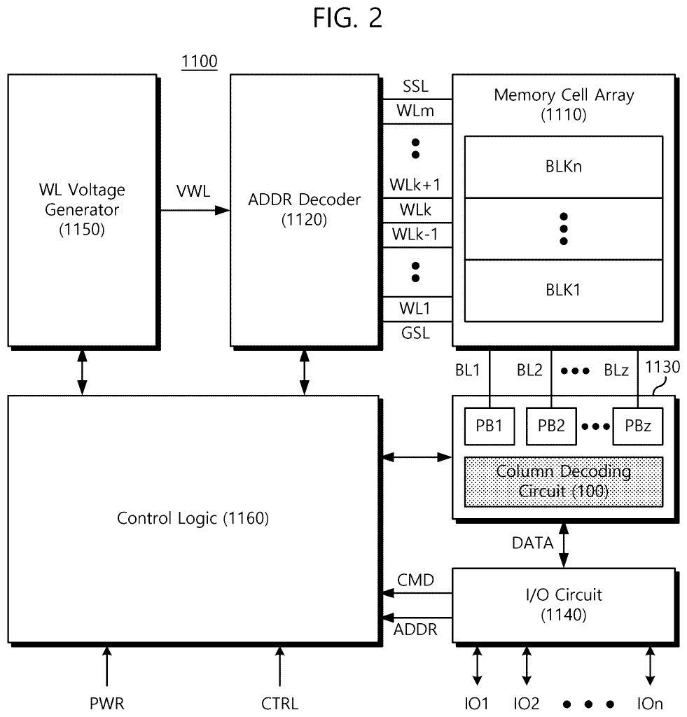

FIG. 2 is a block diagram illustrating an example of the memory device illustrated in FIG. 1 according to some example embodiments. The storage device 1000 of FIG. 1 may be a flash storage device based on flash memory. For example, the storage device 1000 may be implemented as an SSD, UFS, and/or memory card, etc.

Referring to FIGS. 1 and 2, the memory device 1100 may include a memory cell array 1110 and a peripheral circuit. The peripheral circuit may include an address decoder 1120, a page buffer circuit 1130, an input/output circuit 1140, a wordline voltage generator 1150, and control logic 1160. The page buffer circuit 1130 may include a column decoding circuit 100. Alternatively, in some example embodiments, a column decoding circuit 100 may be disposed or located between the page buffer circuit 1130 and the input/output circuit 1140 separately from the page buffer circuit 1130.

According to some example embodiments, the memory cell array 1110 may include a plurality of memory blocks BLK1 to BLKn. Each memory block may be configured as a plurality of pages. Each page may include a plurality of memory cells. Each memory cell may store multi-bit data (for example, two or more bits). Each memory block may correspond to an erase unit, and each page may correspond to a read and/or write unit.

According to some example embodiments, the memory cell array 1110 may be formed in a direction perpendicular to a substrate. It will be understood that elements and/or properties thereof (e.g., structures, surfaces, directions, or the like), which may be referred to as being “perpendicular,” parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to other elements and/or properties thereof. A gate electrode layer and an insulation layer may be alternately deposited or located on the substrate. It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element. Each memory block (for example, BLK1) may be connected to one or more string selection lines SSL, a plurality of wordlines WL1 to WLm, and one or more ground selection lines GSL. WLk is a selected wordline and the remaining wordlines (WL1 to WLk−1, WLk+1 to WLm) are unselected wordlines.

According to some example embodiments, the address decoder 1120 may be connected to the memory cell array 1110 through string selection lines SSL, the ground selection lines GSL, and wordlines WL1 to WLm. The address decoder 1120 may select a wordline during a program operation or read operation. The address decoder 1120 may receive the wordline voltage VWL from the wordline voltage generator 1150 and provide, transmit, send, or transfer a program voltage or read voltage to the selected wordline.

According to some example embodiments, the page buffer circuit 1130 may be connected to the memory cell array 1110 through bitlines BL1 to BLz. The page buffer circuit 1130 may temporarily store data to be stored in the memory cell array 1110 or data read from the memory cell array 1110. The page buffer circuit 1130 may include page buffers PB1 to PBz connected to respective bitlines BL1 to BLz. Each page buffer may include a plurality of latches to store or read multi-bit data.

According to some example embodiments, the input/output circuit 1140 may be internally connected to the page buffer circuit 1130 through data lines and externally connected to the memory controller (e.g., refer to FIG. 1, 1200) through the input/output lines IO1 to IOn. The input/output circuit 1140 may receive program data from the memory controller 1200 during a program operation. In some example embodiments, the input/output circuit 1140 may provide, transmit, or send data read from the memory cell array 1110 to the memory controller 1200 during a read operation.

According to some example embodiments, the wordline voltage generator 1150 may receive internal power from the control logic 1160 and generate a wordline voltage VWL required to read or write data. The wordline voltage VWL may be provided, transmitted, or sent to a selected wordline sWL or unselected wordlines uWL through the address decoder 1120.

According to some example embodiments, the wordline voltage generator 1150 may include a program voltage generator and a pass voltage generator. The program voltage generator may generate a program voltage Vpgm provided, transmitted, or sent to the selected wordline sWL during a program operation. The pass voltage generator may generate a pass voltage Vpass provided, transmitted, or sent to the selected wordline sWL and the unselected wordlines uWL.

According to some example embodiments, the wordline voltage generator 1150 may include a read voltage generator and a read pass voltage generator. The read voltage generator may generate a select read voltage Vrd provided, transmitted, or sent to the select wordline sWL during a read operation. The read pass voltage generator may generate a read pass voltage Vrdps provided, transmitted, or sent to unselected wordlines uWL. The read pass voltage Vrdps may be a voltage sufficient to turn on memory cells connected to the unselected wordlines uWL during a read operation.

According to some example embodiments, the control logic 1160 may control operations such as read, write, and erase of the memory device 1100 using commands CMD, addresses ADDR, and control signals CTRL provided, transmitted, or sent from the memory controller 1200 illustrated in FIG. 1. The addresses ADDR may include a block selection address for selecting one memory block, a row address for selecting one page, and a column address for selecting one memory cell.

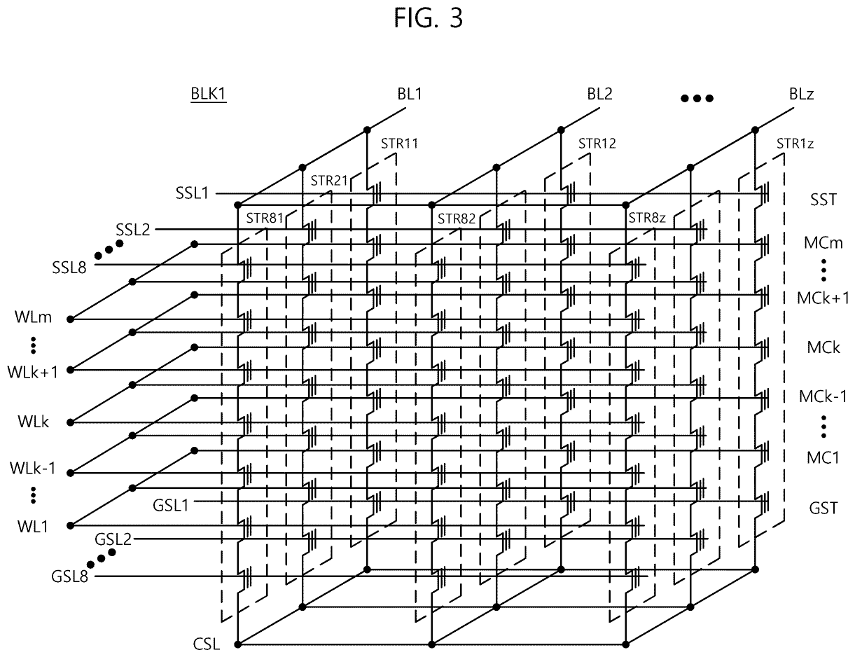

FIG. 3 is a circuit diagram illustrating an example of a memory block BLK1 of the memory cell array illustrated in FIG. 2 according to some example embodiments. Referring to FIG. 3, in the memory block BLK1, a plurality of cell strings STR11 to STR8z may be formed between the bitlines BL1 to BLz and a common source line CSL. Each cell string includes a string selection transistor SST, a plurality of memory cells MC1 to MCm, and a ground selection transistor GST.

According to some example embodiments, the string selection transistors SST may be connected with string selection lines SSL1 to SSL8. The ground selection transistors GST may be connected with ground selection lines GSL1 to GSL8. The string selection transistors SST may be connected with the bitlines BL1 to BLz, and the ground selection transistors GST may be connected with the common source line CSL.

According to some example embodiments, the first to m wordlines WL1 to WLm may be connected with the plurality of memory cells MC1 to MCm in a row direction. The first to z bitlines BL1 to BLz may be connected with the plurality of memory cells MC1 to MCm in a column direction.

According to some example embodiments, the first wordline WL1 may be placed above the first to eighth ground selection lines GSL1 to GSL8. The first memory cells MC1 that are placed at the same height from the substrate may be connected with the first wordline WL1. The m wordline WLm may be placed below the first to eighth string selection lines SSL1 to SSL8. The m memory cells MCm that are placed at the same height from the substrate may be connected with the m wordline WLm. In a similar manner, the second to m−1 memory cells MC2 to MCm−1 that are placed at the same heights from the substrate may be respectively connected with the second to m−1 wordlines WL2 to WLm−1.

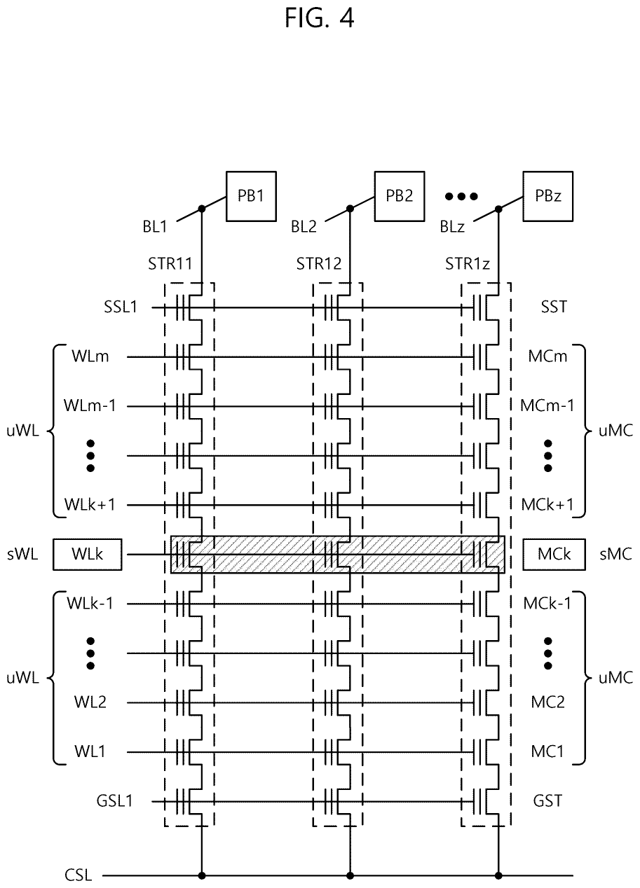

FIG. 4 is a circuit diagram illustrating cell strings selected by the first string selection line SSL1 among the cell strings of the memory block BLK1 illustrated in FIG. 3 according to some example embodiments. The 11th to 1z cell strings STR11 to STR1z may be selected by the first string selection line SSL1. The 11th to 1z cell strings STR11 to STR1z may be connected to the first to z bitlines BL1 to BLz, respectively. The first to z page buffers PB1 to PBz may be connected to the first to z bitlines BL1 to BLz, respectively.

According to some example embodiments, the 11th cell string STR11 may be connected to the first bitline BL1 and the common source line CSL. The 11th cell string STR11 may include string selection transistors SST selected by the first string selection line SSL1 and first to m memory cells MC1 to MCm connected to the first to m wordlines WL1 to WLm, and ground selection transistors GST selected by the first ground selection line GSL1. The 12th cell string STR12 may be connected to the second bitline BL2 and the common source line CSL. The 1z cell string STR1z may be connected to the z bitline BLz and the common source line CSL.

According to some example embodiments, the first wordline WL1 and the m wordline WLm may be edge wordlines. The second wordline WL2 and the m−1 wordline WLm−1 may be edge adjacent wordlines. The k wordline WLk may be a selected wordline sWL. The k−1 wordline WLk−1 and the k+1 wordline WLk+1 may be adjacent wordlines adjacent to the selected wordline sWL. When the k wordline WLk is a selected wordline sWL, the remaining wordlines WL1 to WLk−1 and WLk+1 to WLm may be unselected wordlines uWL.

According to some example embodiments, the first memory cells MC1 and the m memory cells MCm may be edge memory cells. The second memory cells MC2 and the m−1 memory cells MCm−1 may be edge adjacent memory cells. The k memory cells MCk may be selected memory cells sMC. The k−1 memory cells MCk−1 and the k+1 memory cells MCk+1 may be memory cells adjacent to the selected memory cells (hereinafter referred to as adjacent memory cells). When the k memory cells MCk are selected memory cells sMC, the remaining memory cells MC1 to MCk−1 and MCk+1 to MCm may be unselected memory cells uMC.

According to some example embodiments, a set of memory cells selected by one string selection line and connected to one wordline may be one page. For example, memory cells selected by the first string selection line SSL1 and connected to the k wordline WLk may be one page. For example, eight pages may be configured on the k wordline WLk. Among the eight pages, a page connected to the first string selection line SSL1 is a selected page, and the pages connected to the second to eighth string selection lines SSL2 to SSL8 are unselected pages.

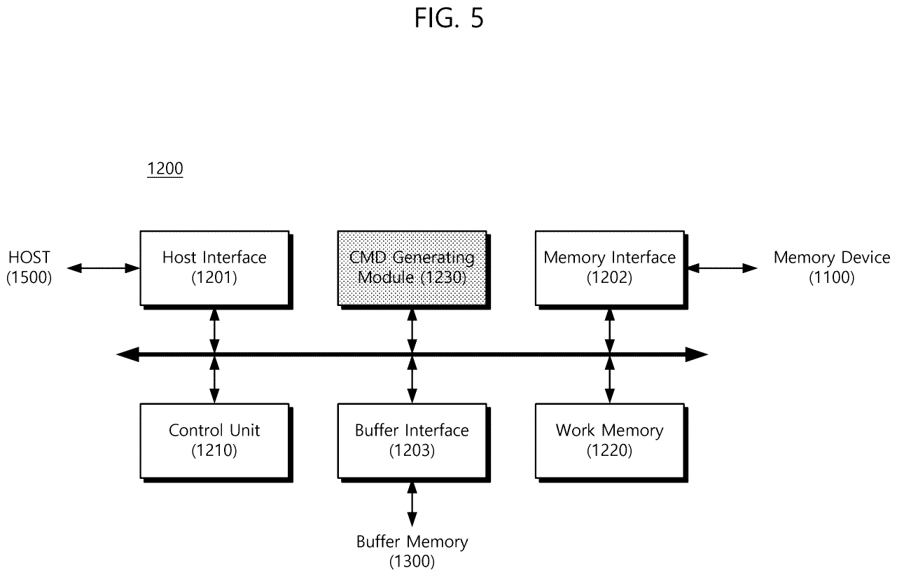

FIG. 5 is a block diagram illustrating the memory controller of FIG. 1 according to some example embodiments. Referring to FIG. 5, the memory controller 1200 includes a host interface 1201, a memory interface 1202, a buffer interface 1203, a control unit 1210, a work memory 1220 and/or a command generating module 1230.

Although not illustrated in FIG. 5, in some example embodiments, the memory controller 1200 may further include various other components. For example, the memory controller 1200 may further include an ECC circuit, or the like. The ECC circuit may generate an error correction code (ECC) to correct fail bits or error bits of data received from the memory device 1100. According to some example embodiments, the memory controller 1200 and each of the control unit 1210, and/or a command generating module 1230 may include or be implemented in one or more processing circuitries such as hardware including logic circuits; a hardware/software combination such as a processor executing software; or a combination thereof. For example, the processing circuitries more specifically may include, but are not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

According to some example embodiments, the host interface 1201 may provide an interface between the host 1500 and the memory controller 1200. Standard interfaces include various interface methods such as an advanced technology attachment (ATA), a serial ATA (SATA), an external SATA (e-SATA), a small computer small interface (SCSI), a serial attached SCSI (SAS), a peripheral component interconnection (PCI), a PCI express (PCI-E), an IEEE 1394, an universal serial bus (USB), a secure digital (SD) card, a multi media card (MMC), an embedded multi media card (eMMC), universal flash storage (UFS), a compact flash (CF) card interface, or the like.

According to some example embodiments, the memory interface 1202 may provide an interface between the memory device 1100 and the memory controller 1200. For example, write or read data may be transmitted/sent to and received from the memory device 1100 through the memory interface 1202. The memory interface 1202 may provide, transmit, or send commands and addresses to the memory device 1100. In some example embodiments, the memory interface 1202 may provide, transmit, or send data read from the memory device 1100 to the memory controller 1200.

According to some example embodiments, the buffer interface 1203 may provide an interface between the buffer memory 1300 and the memory controller 1200. For example, data temporarily stored in the buffer memory 1300 may be transmitted or sent to and received from the buffer memory 1300 through the buffer interface 1203.

According to some example embodiments, the control unit 1210 may include a central processing unit, a microprocessor, or the like, and may control the overall operation of the memory controller 1200. The control unit 1210 may drive firmware loaded in the work memory 1220 to control the memory controller 1200.

According to some example embodiments, the work memory 1220 may be implemented with various memories, for example, at least one of a cache memory, a DRAM, a SRAM, a PRAM, and a flash memory, but example embodiments are not limited thereto. The work memory 1220 may drive a flash transition layer (FTL) under the control of the control unit 1210.

According to some example embodiments, the FTL may be firmware or a program for efficiently managing the memory device 1100. Unlike a hard disk, the memory device 1100 does not support an overwrite function. Therefore, to modify data written on a page, it is necessary to copy all valid data (or valid pages) in a previous block to which the page belongs to another empty block and delete the previous block. This process may perform multiple page copy (read and write pages) and erase operations.

According to some example embodiments, the FTL is used between the host 1500 and the memory device 1100 to reduce the number of page copy and erase operations. The FTL may include an address mapping module, a garbage collection module and/or a wear-leveling module, or the like. In some example embodiments, the FTL and each of the address mapping module, garbage collection module and/or wear-level module may include or be implemented in one or more processing circuitries such as hardware including logic circuits; a hardware/software combination such as a processor executing software; or a combination thereof.

According to some example embodiments, the address mapping module may perform an address mapping operation on a page-by-page or block-by-block basis. The page address mapping operation is an operation which converts a logical page address received from the file system into a physical page address within the memory device 1100. For this purpose, a page-level address mapping table must be maintained in the work memory 1220. The page address mapping operation may provide excellent or improved garbage collection performance but may require a large address mapping table.

According to some example, the garbage collection module may perform a garbage collection operation by referring to the address mapping table. For example, to secure one or more free blocks, the garbage collection module may use an address mapping table, record one or more valid data stored in a source block to a random block, and secure a free block by erasing the source block in which all the valid data have been moved.

According to some example embodiments, the wear-leveling module may manage wear-level of memory cells of the memory device 1100. Memory cells may be deteriorated by write and erase operations, etc. Deteriorated memory cells may cause defects. The wear-leveling module may manage program and erase cycles for the memory cell array 1110 to prevent or reduce specific cell areas from wearing out faster than other cell areas. The wear-leveling module may control the address mapping module such that program and erase times may be equally assigned to cell areas of the memory cell array 1110.

According to some example embodiments, the command generating module 1230 may generate a command for controlling a memory operation of the memory device 1100 based on a request received from the host 1500. As an example, the command generating module 1230 may set a format of the command.

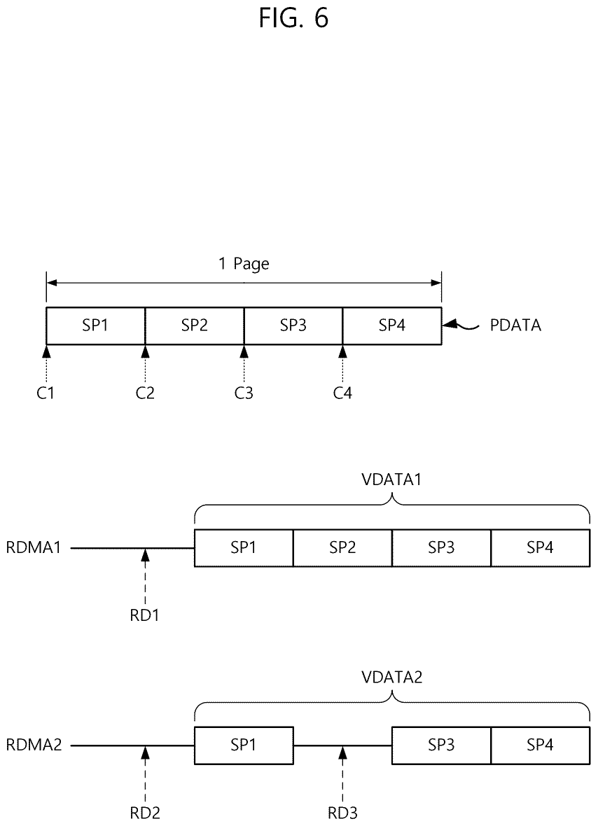

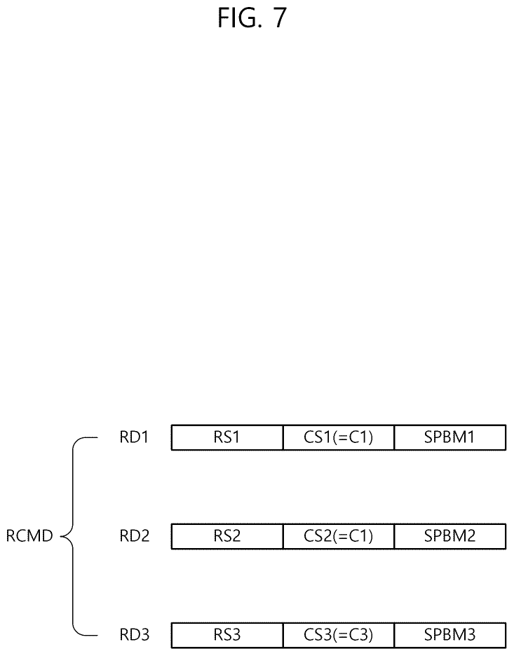

FIG. 6 is a diagram illustrating a first read mode of a memory device of FIG. 2 according to some example embodiments. FIG. 7 is a diagram illustrating configuration of read commands according to a first read mode of FIG. 6 according to some example embodiments. Referring to FIGS. 6 and 7, the memory device 1100 may perform a read operation RDMA based on a read command RCMD. The memory device 1100 may perform a read operation RDMA on a page basis.

According to some example embodiments, the memory controller 1200 may transmit, provide, or send a read command RCMD to the memory device 1100 based on a read request from the host 1500. For example, the command generating module 1230 of FIG. 5 may generate a read command RCMD based on a first read mode. As an example, the read command RCMD may include row selection information RS and column selection information CS.

According to some example embodiments, the memory device 1100 may perform the read operation RDMA by decoding the read command RCMD. For example, the address decoder 1120 may select a wordline based on the row selection information RS of the read command RCMD. Page data PDATA corresponding to a selected wordline may be temporarily stored in the page buffers PB1 to PBz of FIG. 2. The column decoding circuit 100 may transfer valid data VDATA from the page data PDATA stored in the page buffers PB1 to PBz to the input/output circuit 1140 based on the column selection information CS of the read command RCMD.

According to some example embodiments, during a read operation RDMA, the memory device 1100 may divide one page into a plurality of sub-pages. The memory device 1100 may output a valid sub-page (or valid data VDATA) corresponding to the read command RCMD among the plurality of sub-pages.

For example, when one page has a capacity of 16 KB, one page may be divided into four sub-pages SP1, SP2, SP3 and SP4 of 4 KB each. The first sub-page SP1 may start at a first column start position C1. The second sub-page SP2 may start at a second column start position C2. The third sub-page SP3 may start at a third column start position C3. The fourth sub-page SP4 may start at a fourth column start position C4.

According to some example embodiments, the memory device 1100 may output valid data VDATA including consecutive sub-pages. For example, in FIG. 6, during a first read operation RDMA1, the memory device 1100 may output first valid data VDATA1 based on a first read command RD1.

For example, in FIG. 7, the first read command RD1 may include first column selection information CS1. The first column selection information CS1 may include the first column start position C1 as a reading start position. Accordingly, the first valid data VDATA1 may include the first sub-page SP1 to the fourth sub-page SP4 after the first column start position C1.

According to some example embodiments, the memory device 1100 may output valid data VDATA including non-contiguous sub-pages. For example, in FIG. 6, during a second read operation RDMA2, the memory device 1100 may output second valid data VDATA2 based on a second read command RD2 and a third read command RD3.

For example, in FIG. 7, the second read command RD2 may include second column selection information CS2. The second column selection information CS2 may include the first column start position C1 as a reading start position. The third read command RD3 may include third column selection information CS3. The third column selection information CS3 may include the third column start position C3 as a reading start position. Accordingly, the second valid data VDATA2 is the first sub-page SP1 after the first column start position C1, and the third sub-page SP3 and the fourth sub-page SP4 after the third column start position C3. During the second read operation RDMA2, the second sub-page SP2 may be excluded from the second valid data VDATA2.

According to some example embodiments, the read command RCMD may include a sub-page bitmap SPBM. In the first read mode, the sub-page bitmap SPBM may be disabled. For example, in the first read mode, the sub-page bitmap SPBM may be set to “0”. For example, in FIG. 7, a first sub-page bitmap SPBM1, a second sub-page bitmap SPBM2 and a third sub-page bitmap SPBM3 may be set to “0”.

As described above, in some example embodiments, the memory device 1100 may perform a read operation according to the first read mode. When performing the read operation in the first read mode, a read command RCMD may include row selection information RS and column selection information CS. However, in some example embodiments, when performing the read operation on valid data VDATA including non-consecutive sub-pages in the first read mode, the memory device 1100 may receive two read commands (for example, a second read command RD2 and a third read command RD3).

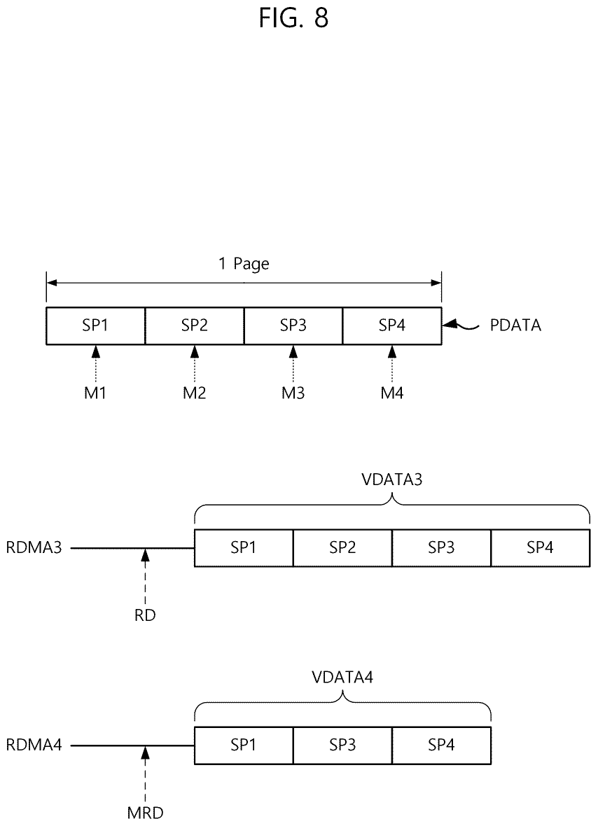

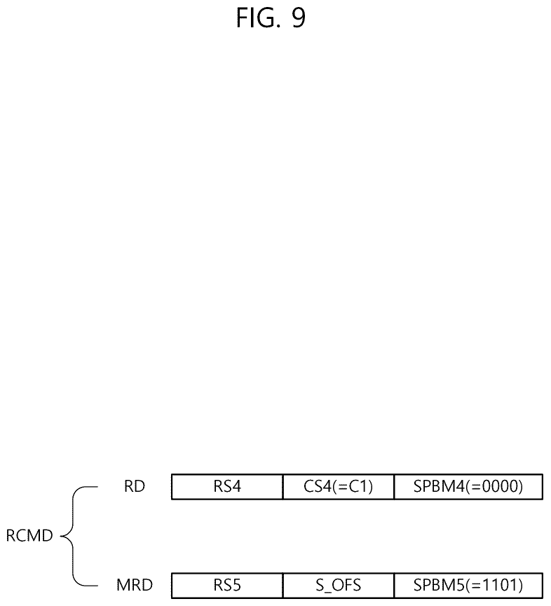

FIG. 8 is a diagram illustrating a second read mode of a memory device of FIG. 2 according to some example embodiments. FIG. 9 is a diagram illustrating configuration of read commands according to a second read mode of FIG. 8 according to some example embodiments. Referring to FIGS. 8 and 9, the memory device 1100 may perform a read operation RDMA based on a read command RCMD. The memory device 1100 may perform a read operation RDMA on a page basis.

According to some example embodiments, the memory controller 1200 may transmit, provide, or send a read command RCMD to the memory device 1100 based on a read request from the host 1500. For example, when a read operation RDMA corresponding to valid data VDATA including non-contiguous sub-pages is performed, the command generating module 1230 of FIG. 5 may generate a read command RCMD based on a second read mode. For example, the read command RCMD may include row selection information RS, sub-data offset size S_OFS and sub-page bitmap information SPBM.

According to some example embodiments, the memory device 1100 may perform a read operation RDMA by decoding a read command RCMD. For example, the address decoder 1120 may select a wordline based on row selection information RS of the read command RCMD. Page data PDATA corresponding to the selected wordline may be temporarily stored in the page buffers PB1 to PBz of FIG. 2. The column decoding circuit 100 may transmit, provide, or send valid data VDATA among the page data PDATA stored in the page buffers PB1 to PBz to the input/output circuit 1140 based on a sub-data offset size S_OFS and sub-page bitmap information SPBM of the read command RCMD.

According to some example embodiments, during a read operation RDMA, the memory device 1100 may divide one page into a plurality of sub-pages. The memory device 1100 may output a valid sub-page (or valid data VDATA) corresponding to the read command RCMD among the plurality of sub-pages.

For example, when one page has a capacity of 16 KB, one page may be divided into four sub-pages SP1, SP2, SP3 and SP4 of 4 KB each. The first sub-page SP1 may correspond to a first bitmap M1. The second sub-page SP2 may correspond to a second bitmap M2. The third sub-page SP3 may correspond to a third bitmap M3. The fourth sub-page SP4 may correspond to a fourth bitmap M4.

According to some example embodiments, when outputting valid data VDATA including consecutive sub-pages, the memory device 1100 may perform a read operation RDMA in a first read mode. For example, in FIG. 8, during a third read operation RDMA3, the memory device 1100 may output third valid data VDATA3 based on a read command RD.

According to some example embodiments, when outputting valid data VDATA including non-contiguous sub-pages, the memory device 1100 may perform a read operation RDMA in a second read mode. For example, in FIGS. 8 and 9, during a fourth read operation RDMA4, the memory device 1100 may read fourth valid data VDATA4 based on the sub-data offset size S_OFS and the sub-page bitmap information SPBM.

For example, in FIG. 9, a bitmap read command MRD may include sub-data offset size S_OFS and fifth sub-page bitmap information SPBM5. The sub-data offset size S_OFS may be set to 4 KB. The fifth sub-page bitmap information SPBM5 may be indicated as 4-bit information (for example, 1101) according to the positions of valid sub-pages SP1, SP2, SP3 and SP4.

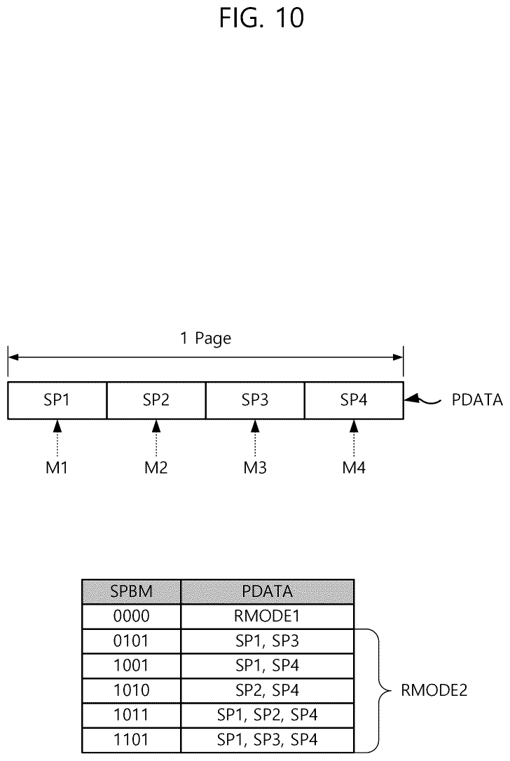

FIG. 10 is a diagram illustrating bitmap information corresponding to valid data including non-contiguous sub-pages in a second read mode of a memory device of FIG. 2 according to some example embodiments. Referring to FIG. 10, sub-page bitmap information SPBM may indicate a valid sub-page among sub-pages SP1, SP2, SP3 and SP4 of one page data PDATA.

According to some example embodiments, in the second read mode RMODE2, a bitmap read command MRD may include sub-data offset size S_OFS and sub-page bitmap information SPBM. For example, when one page is divided into four sub-pages SP1, SP2, SP3 and SP4, the first to fourth sub-pages SP1, SP2, SP3 and SP4 may correspond to first to fourth bitmaps M1, M2, M3 and M4. The sub-page bitmap information SPBM may indicate the locations of valid sub-pages within one page.

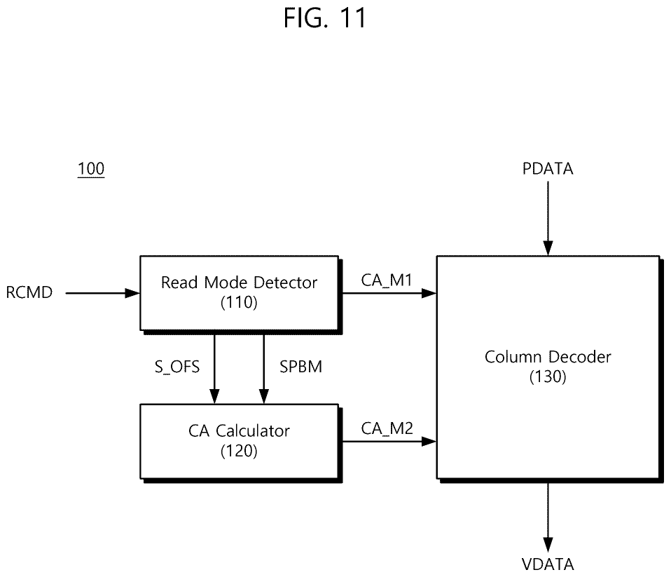

FIG. 11 is a diagram illustrating an example of a column decoding circuit of FIG. 2 according to some example embodiments. Referring to FIGS. 2 and 11, the column decoding circuit 100 may include a read mode detector 110, a column address calculator 120 and/or a column decoder 130.

According to some example embodiments, the read mode detector 110 may detect a read mode corresponding to a read command RCMD. For example, when sub-page bitmap information SPBM is inactive or deactivated (for example, 0000), the read mode detector 110 may determine a first read mode RMODE1. When the first read mode is detected, the read mode detector 110 may transmit, provide, or send a first mode column address CA_M1 to the column decoder 130.

When the sub-page bitmap information SPBM is one of values included in the bitmap table of FIG. 10, the read mode detector 110 may determine a second read mode RMODE2. When the second read mode RMODE2 is detected (e.g., activated), the read mode detector 110 may transmit, provide, or send sub-data offset size S_OFS and sub-page bitmap information SPBM included in the read command RCMD to the column address calculator 120.

According to some example embodiments, when receiving the sub-data offset size S_OFS and the sub-page bitmap information SPBM from the read mode detector 110, the column address calculator 120 may transmit, provide, or send a second mode column address CA_M2 to the decoder 130. The column address calculator 120 may not operate when there is no signal received from the read mode detector 110.

According to some example embodiments, when receiving the first mode column address CA_M1, the column decoder 130 may output valid data VDATA including consecutive sub-pages among page data PDATA stored in the page buffers PB1 to PBz like the first read operation RDMA1 of FIG. 6. When receiving the second mode column address CA_M2, the column decoder 130 may output valid data VDATA including non-contiguous sub-pages among page data PDATA, as illustrated in the bitmap table of FIG. 10. For example, as illustrated in the bitmap table of FIG. 10, when the sub-page bitmap information SPBM is 0101, the first sub-page SP1 and the third sub-page SP3 is output as valid data VDATA. When the sub-page bitmap information SPBM is 1001, the first sub-page SP1 and the fourth sub-page SP4 is output as valid data VDATA. When the sub-page bitmap information is 1010, the second sub-page SP2 and the fourth sub-page SP4 is output as valid data VDATA. When the sub-page bitmap information SPBM is 1011, the first, second, and fourth sub-pages SP1, SP2, SP4, are output as valid data VDATA. When the sub-page bitmap information SPBM is 1101, the first, third, and fourth sub-pages SP1, SP3, SP4 are output as valid data VDATA.

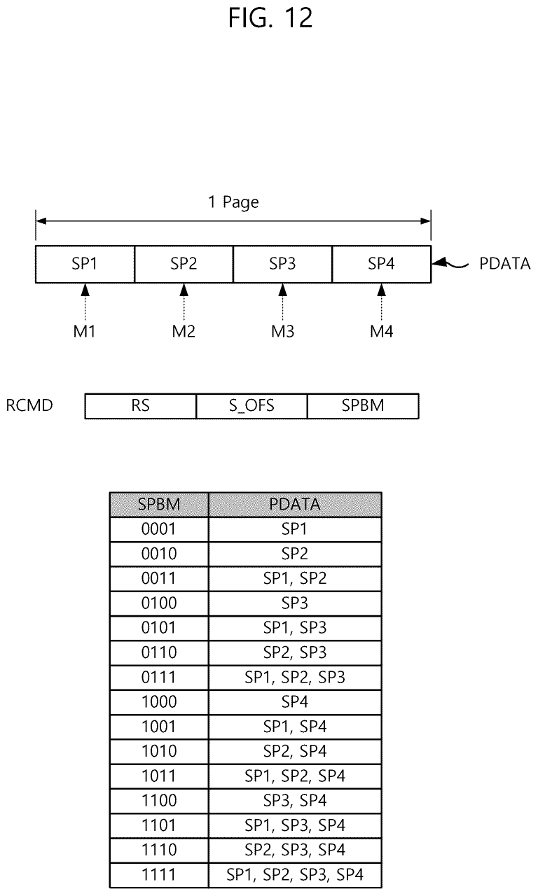

FIG. 12 is a diagram illustrating an example of a reading method of a memory device of FIG. 2 according to some example embodiments. Referring to FIGS. 2 and 12, the memory device 1100 may perform a read operation RDMA based on a read command RCMD. The read command RCMD may include row selection information RS, sub-data offset size S_OFS and/or sub-page bitmap information SPBM.

According to some example embodiments, the command generating module 1230 of FIG. 5 may generate the read command RCMD including the sub-data offset size S_OFS and the sub-page bitmap information SPBM based on a read request from the host 1500. For example, the sub-page bitmap information SPBM may indicate locations of valid sub-pages within one page. The sub-data offset size S_OFS may indicate the size of one sub-page.

According to some example embodiments, the column decoding circuit 100 of FIG. 2 may output valid data VDATA based on the read command RCMD. For example, the column decoding circuit 100 may output sub-pages corresponding to the sub-page bitmap information SPBM as the valid data VDATA, as illustrated in a bitmap table of FIG. 12. In FIG. 12, the column decoding circuit 100 may output the valid data VDATA through one read command RCMD regardless of whether sub-pages included in the valid data VDATA are consecutive.

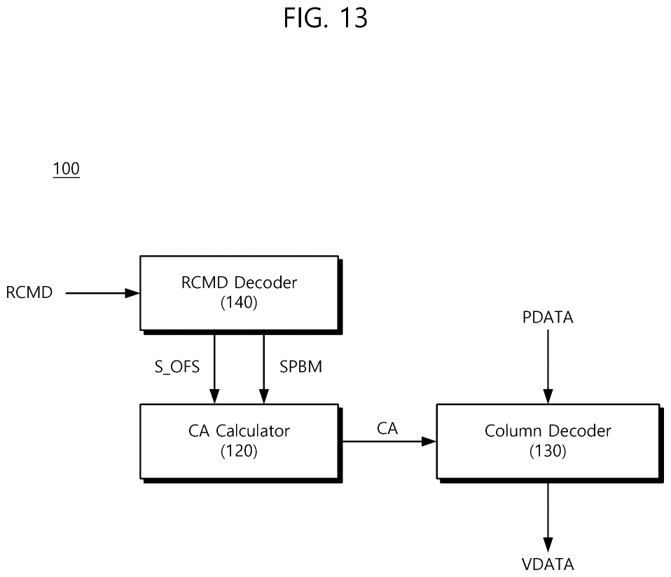

FIG. 13 is a diagram illustrating an example embodiment of a column decoding circuit of FIG. 2 according to some example embodiments. Referring to FIGS. 2, 12 and 13, the column decoding circuit 100 may include a column address calculator 120, a column decoder 130 and/or a read command decoder 140.

According to some example embodiments, the read command decoder 140 may output sub-data offset size S_OFS and sub-page bitmap information SPBM based on a read command RCMD. The column address calculator 120 may output a column address CA of a valid sub-page based on the sub-data offset size S_OFS and the sub-page bitmap information SPBM. The column decoder 130 may output valid data VDATA as illustrated in the bitmap table of FIG. 12 among page data PDATA stored in the page buffers PB1 to PBz based on the column address CA.

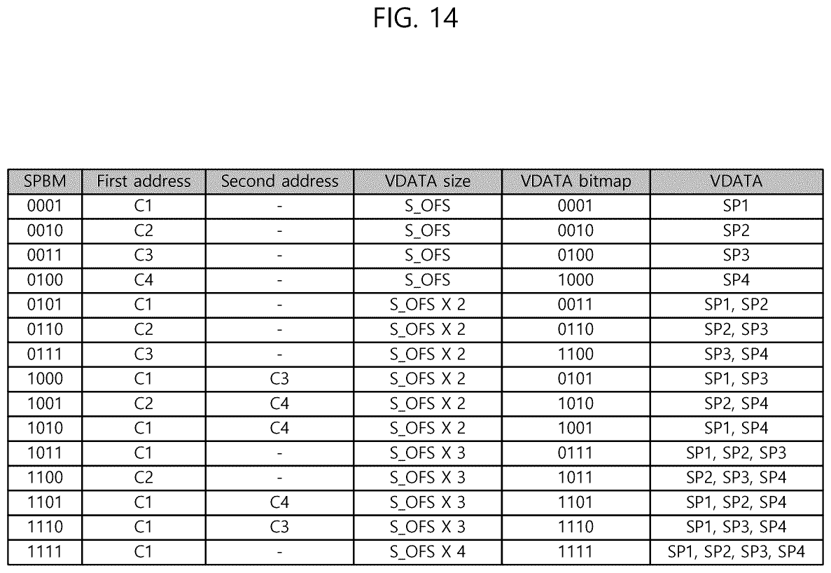

FIG. 14 is a diagram illustrating a lookup table according to an example of a reading method of a memory device of FIG. 2 according to some example embodiments. Referring to FIGS. 2 and 14, the column decoding circuit 100 of FIG. 13 may output valid data VDATA based on a lookup table of FIG. 14.

According to some example embodiments, sub-page bitmap information SPBM included in a read command RCMD may be converted into a valid data bitmap (VDATA bitmap) based on the lookup table of FIG. 14. For example, the sub-page bitmap information SPBM may be matched to information about valid sub-pages. The information about valid sub-pages may include a first address, a second address, a valid data size (VDATA size), a valid data bitmap (VDATA bitmap) and/or valid data VDATA. The first address and the second address may indicate the starting positions of valid sub-pages. The valid data size (VDATA size) may represent the total data size included in the valid data VDATA.

According to the present inventive concepts, it may be possible to shorten a read operation time by performing a read operation on non-contiguous sub-pages within one page through transmitting, providing, or sending a single read command.

While the present inventive concepts have been described with reference to some example embodiments thereof, it will be apparent to those of ordinary skill in the art that various changes and modifications may be made thereto without departing from the spirit and scope of the present inventive concepts as set forth in the following claims.

What is claimed is:

1. A memory device, comprising:
a memory cell array including a plurality of memory cells;
a page buffer circuit connected to the plurality of memory cells through bitlines and configured to read data stored in the plurality of memory cells in page units; and
a column decoding circuit configured to output non-contiguous sub-pages among page data stored in the page buffer circuit as valid data based on sub-page bitmap information included in a read command during a read operation.

2. The memory device of claim 1, wherein
the read command is configured to include sub-page offset information, and
the column decoding circuit is configured to determine each of the non-contiguous sub-pages based on the sub-page bitmap information and the sub-page offset information.

3. The memory device of claim 1, wherein the column decoding circuit, in a first read mode, is configured to output at least one sub-page consecutive from a column address included in the read command as valid data when the sub-page bitmap information is deactivated.

4. The memory device of claim 1, wherein the column decoding circuit, in a second read mode, is configured to output the non-contiguous sub-pages at positions corresponding to the sub-page bitmap information as valid data when the sub-page bitmap information is activated.

5. The memory device of claim 1, wherein the column decoding circuit is configured to:
output a first mode column address based on a column address included in the read command in a first read mode when the sub-page bitmap information is deactivated, or
output the sub-page bitmap information and sub-page offset information included in the read command in a second read mode when the sub-page bitmap information is activated.

6. The memory device of claim 5, wherein the column decoding circuit is configured to output at least one consecutive sub-page of the page data based on the first mode column address in the first read mode.

7. The memory device of claim 5, wherein the column decoding circuit is configured to output a second mode column address based on the sub-page bitmap information and the sub-page offset information in the second read mode.

8. The memory device of claim 7, wherein the column decoding circuit is configured to output the non-contiguous sub-pages of the page data based on the second mode column address in the second read mode.

9. A memory device, comprising:
a memory cell array including a plurality of memory cells;
an address decoder connected to the plurality of memory cells through wordlines and configured to select one wordline based on a read command;
a page buffer circuit connected to the plurality of memory cells through bitlines and configured to temporarily store page data stored in memory cells connected to the selected wordline; and
a column decoding circuit configured to output at least one sub-page selected among the page data based on sub-page offset information and sub-page bitmap information included in the read command as valid data.

10. The memory device of claim 9, wherein
the page data is configured to be divided into a number of sub-pages, and
the sub-page bitmap information is configured to be a number of bits.

11. The memory device of claim 10, wherein each of the bits of the sub-page bitmap information is configured to indicate a location of each of the sub-pages.

12. The memory device of claim 9, wherein the sub-page offset information is configured to indicate a size of the at least one sub-page.

13. The memory device of claim 9, wherein the column decoding circuit is configured to output the sub-page offset information and the sub-page bitmap information based on the read command.

14. The memory device of claim 13, wherein the column decoding circuit is configured to generate a column address corresponding to the at least one sub-page based on the sub-page offset information and the sub-page bitmap information.

15. The memory device of claim 14, wherein the column decoding circuit is configured to output the at least one sub-page of the page data based on the column address.

16. The memory device of claim 9, wherein the column decoding circuit is configured to store a lookup table including a valid data bitmap indicating a location of the at least one sub-page in response to the sub-page bitmap information.

17. The memory device of claim 16, wherein the lookup table further includes a first start address, a second start address and a valid data size corresponding to the at least one sub-page.

18. A storage device, comprising:
a memory device including a plurality of memory cells; and
a memory controller configured to send a read command including sub-page bitmap information to the memory device to read data stored in the plurality of memory cells,
the memory device configured to select a wordline based on the read command and output non-contiguous sub-pages as valid data based on the sub-page bitmap information among page data stored in memory cells connected to the selected wordline.

19. The storage device of claim 18, wherein the memory device, in a first read mode, is configured to output at least one sub-page consecutive from a column address included in the read command as valid data when the sub-page bitmap information is deactivated.

20. The storage device of claim 18, wherein the memory device, in a second read mode, is configured to output non-contiguous sub-pages at positions corresponding to the sub-page bitmap information as valid data when the sub-page bitmap information is activated.
